(19) United States
(12) Patent Application Publication
(10) Pub. No.: US 2026/0304887 A1
(43) Pub. Date: Oct. 1, 2026

(54) LATERALLY-DIFFUSED METAL-OXIDE-SEMICONDUCTOR DEVICES WITH A FIELD PLATE AND A RECESSED DRAIN

(71) Applicant: GlobalFoundries Singapore Pte. Ltd., Singapore (SG)

(72) Inventors: Yong Wah See, Singapore (SG); Guowei Zhang, Singapore (SG); Ee Jan Khor, Singapore (SG)

(21) Appl. No.: 19/095,151

(22) Filed: Mar. 31, 2025

(51) Int. Cl. H10D 64/00; H10D 30/01; H10D 30/65; H10D 62/10; H10D 84/83; H10D 64/66

(52) U.S. Cl. CPC H10D 64/117; H10D 30/0281; H10D 30/65; H10D 62/117; H10D 84/83125; H10D 84/835; H10D 64/661

(57) ABSTRACT

Structures for a laterally-diffused metal-oxide-semiconductor device and methods of forming same. The structure comprises a semiconductor substrate including a trench, a source in the semiconductor substrate, and a drain in the semiconductor substrate. The trench has a sidewall, and the drain is positioned inside the trench. A gate is laterally positioned between the drain and the source, and a field plate is adjacent to the first sidewall of the trench. The field plate is laterally positioned between the gate and the drain.

### BACKGROUND

The disclosure relates generally to semiconductor devices and integrated circuit fabrication and, more specifically, to structures for a laterally-diffused metal-oxide-semiconductor device and methods of forming same.

High-voltage integrated circuits used in power electronics typically require robust device structures, such as laterally-diffused metal-oxide-semiconductor devices, capable of withstanding higher voltages than logic field-effect transistors. Laterally-diffused metal-oxide-semiconductor devices may include a source, drain, and gate structure that control the flow of current through the device. Laterally-diffused metal-oxide-semiconductor devices also incorporate features, such as an extended drain, that promote the higher voltage handling capability, as well as increase the breakdown voltage. The performance of a laterally-diffused metal-oxide-semiconductor device is dependent upon the drain-source on-resistance, which represents the total resistance between the drain and the source. High values of the drain-source on-resistance degrade the performance of the laterally-diffused metal-oxide-semiconductor device.

Improved structures for a laterally-diffused metal-oxide-semiconductor device and methods of forming same are needed.

### SUMMARY

In an embodiment, a structure for a laterally-diffused metal-oxide-semiconductor device is provided. The structure comprises a semiconductor substrate including a trench, a source in the semiconductor substrate, and a drain in the semiconductor substrate. The trench has a sidewall, and the drain is positioned inside the trench. A gate is laterally positioned between the drain and the source, and a field plate is adjacent to the sidewall of the trench. The field plate is laterally positioned between the gate and the drain.

In an embodiment, a method of forming a structure for a laterally-diffused metal-oxide-semiconductor device is provided. The method comprises forming a trench in a semiconductor substrate, forming a source in the semiconductor substrate, forming a drain in the semiconductor substrate, and forming a gate laterally positioned between the drain and the source. The trench has a sidewall, and the drain is positioned inside the trench. The method further comprises forming a field plate adjacent to the sidewall of the trench. The field plate is laterally positioned between the gate and the drain.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals are used to indicate like features in the various views.

FIG. 1 is a cross-sectional view of a structure at an initial fabrication stage of a processing method in accordance with embodiments of the invention.

FIG. 2 is a cross-sectional view of the structure at a fabrication stage of the processing method subsequent to FIG. 1.

FIG. 3 is a cross-sectional view of the structure at a fabrication stage of the processing method subsequent to FIG. 2.

FIG. 4 is a cross-sectional view of the structure at a fabrication stage of the processing method subsequent to FIG. 3.

FIG. 5 is a cross-sectional view of the structure at a fabrication stage of the processing method subsequent to FIG. 4.

FIG. 6 is a cross-sectional view of the structure at a fabrication stage of the processing method subsequent to FIG. 5.

FIG. 7 is a cross-sectional view of the structure at a fabrication stage of the processing method subsequent to FIG. 6.

### DETAILED DESCRIPTION

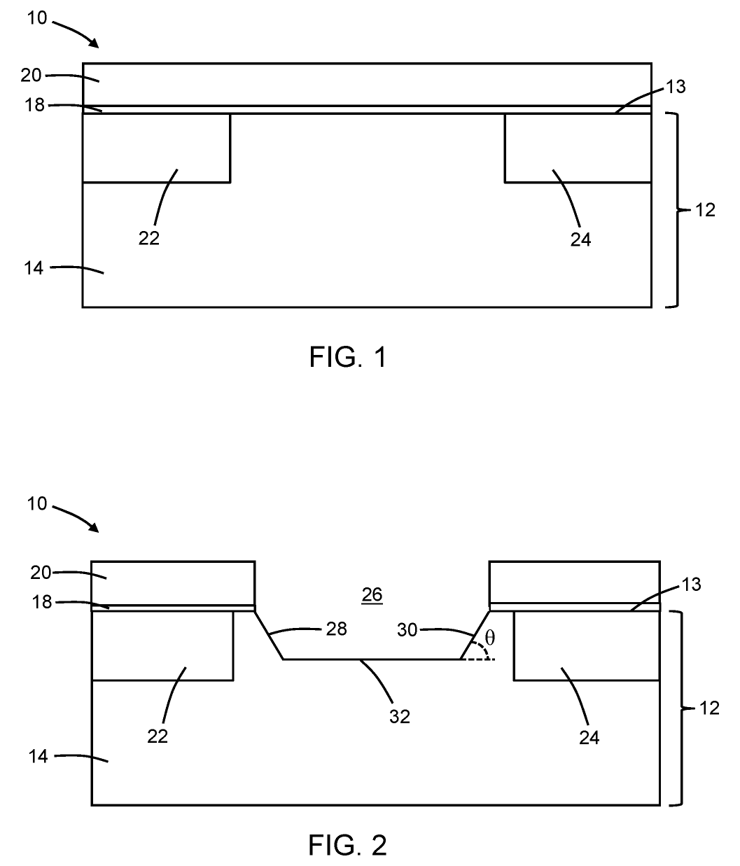

With reference to FIG. 1 and in accordance with embodiments of the invention, a structure 10 for a laterally-diffused metal-oxide-semiconductor device includes a semiconductor substrate 12 and a well 14 that is formed in the semiconductor substrate 12. The semiconductor substrate 12 may be comprised of a semiconductor material, such as single-crystal silicon. In an embodiment, the well 14 may be doped with a concentration of a p-type dopant, such as boron, to provide p-type conductivity. In an embodiment, the well 14 may be formed by introducing a dopant, such as a p-type dopant, by ion implantation into the semiconductor substrate 12. The implantation conditions, such as ion species, dose, and kinetic energy, may be selected to tune the electrical and physical characteristics of the well 14.

A dielectric layer 18 may be formed on, and that overlies, a top surface 13 of the semiconductor substrate 12. The dielectric layer 18 may be comprised of a dielectric material, such as silicon dioxide, that is an electrical insulator. A layer 20 is formed on, and that overlies, the dielectric layer 18. The layer 20 may be comprised of a semiconductor material, such as polycrystalline silicon. The dielectric layer 18 is positioned between the layer 20 and the top surface 13 of the semiconductor substrate 12.

Wells 22, 24 may be formed in respective portions of the semiconductor substrate 12 In an embodiment, the wells 22, 24 may contain a concentration of a p-type dopant, such as boron, to provide p-type conductivity, and the concentration of p-type dopant may be greater than the concentration of p-type dopant in the well 14. The wells 22, 24 may be formed by implanting ions, such as ions including the p-type dopant, with an implantation mask having openings overlying the intended locations for the wells 22, 24 in the semiconductor substrate 12. The implantation conditions, such as ion species, dose, and kinetic energy, may be selected to tune the electrical and physical characteristics of the wells 22, 24. The wells 22, 24 may provide body regions of the laterally-diffused metal-oxide-semiconductor device.

With reference to FIG. 2 in which like reference numerals refer to like features in FIG. 1 and at a subsequent fabrication stage, a trench 26 may be formed in the dielectric layer 18 and the layer 20 by lithography and etching processes. The trench 26 may be extended by the etching process into the semiconductor substrate 12. To that end, an etch mask may be formed by a lithography process over the layer 20. The etch mask may include a layer of a photoresist applied by a spin-coating process, pre-baked, exposed to light projected through a photomask, baked after exposure, and developed with a chemical developer to define openings at the intended locations for the trench 26. An etching process is used to form the trench 26 at the location of the opening in the etch mask.

The trench 26 divides the layer stack including the dielectric layer 18 and the layer 20 into laterally spaced-apart sections. A lower portion of the trench 26 that is inside the semiconductor substrate 12 may have a trench bottom 32 and opposite sidewalls 28, 30 that extend from the top surface 13 of the semiconductor substrate 12 to the trench bottom 32. The trench bottom 32 is recessed relative to the top surface 13 of the semiconductor substrate 12. The sidewalls 28, 30 and the trench bottom 32 define parts of the boundary of the lower portion of the trench 26 that is arranged inside the semiconductor substrate 12. Both sidewalls 28, 30 may be inclined at an angle θ relative to a horizontal plane of the trench bottom 32. In an embodiment, the angle θ may be an acute angle. In an embodiment, the angle θ may be within a range of 30° to less than 90°. In an alternative embodiment, the angle θ may be equal to 90° such that the sidewalls 28, 30 extend perpendicularly relative to the horizontal plane of the trench bottom 32. The sidewall 28 is positioned adjacent to the well 22, and the sidewall 30 is positioned adjacent to the well 24. The depth of the lower portion of the trench 26 may be equal to a distance in a vertical direction between the top surface 13 of the semiconductor substrate 12 and the trench bottom 32.

A drift well 34 may be formed that overlaps with the portion of the trench 26 inside the semiconductor substrate 12 such that the portion of the trench 26 inside the semiconductor substrate 12 is positioned within the drift well 34. The drift well 34 is laterally arranged between the well 22 and the well 24. The drift well 34 may adjoin the sidewalls 28, 30 and the trench bottom 32 of the trench 26. The drift well 34 may have opposite side edges that respectively adjoin the well 22 and the well 24. The drift well 34 is oppositely doped from the well 15. In an embodiment, the drift well 34 may be lightly doped with a concentration of a p-type dopant, such as boron, such that the drift well 34 has p-type conductivity. In an embodiment, the drift well 34 may be formed by introducing a dopant, such as a p-type dopant, by ion implantation into the semiconductor substrate 12. The implantation conditions, such as ion species, dose, and kinetic energy, may be selected to tune the electrical and physical characteristics of the drift well 34. The drift well 34 may be formed using the etch mask used to form the trench 26 such that the drift well 34 is self-aligned to the trench 26. The etch mask may be stripped after forming the trench 26 and the drift well 34.

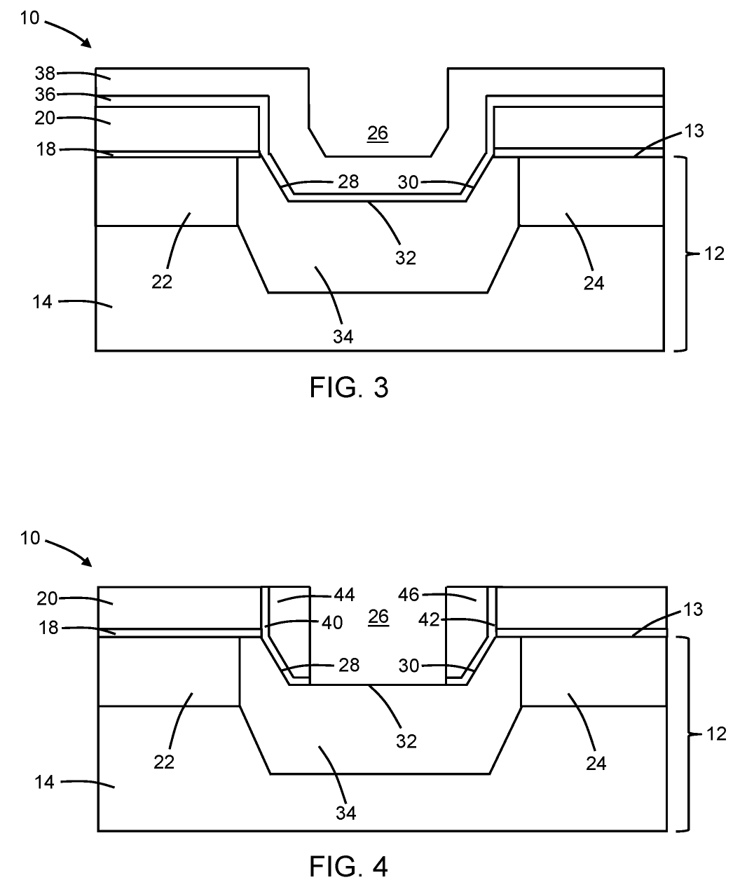

With reference to FIG. 3 in which like reference numerals refer to like features in FIG. 2 and at a subsequent fabrication stage, a layer 36 may be formed that coats the trench 26 and portions of the layer 20 surrounding the trench 26. The layer 36 may be comprised of a dielectric material, such as silicon dioxide, that is an electrical insulator. A layer 38 may be subsequently deposited on the layer 36, including a portion that coats the trench 26. The layer 38 may be comprised of a semiconductor material, such as polycrystalline silicon.

With reference to FIG. 4 in which like reference numerals refer to like features in FIG. 3 and at a subsequent fabrication stage, the layer 36 and the layer 38 may be etched by one or more etching processes to form dielectric spacers 40, 42 from the layer 36 and to form field plates 44, 46 from the layer 38. In an embodiment, the dielectric spacers 40, 42 and the field plates 44, 46 may be formed by an anisotropic etching process, such as a reactive ion etching process. Forming the field plates 44, 46 from the polycrystalline silicon of the layer 38 may promote improved electrical conductivity, thermal stability, reduction of parasitic capacitance, and increased breakdown voltage.

The field plate 44 includes an upper portion arranged above the top surface 13 of the semiconductor substrate 12 and a lower portion between the top surface 13 and the trench bottom 32. The lower portion of the field plate 44 is arranged adjacent to the sidewall 28 of the trench 26. The lower portion of the field plate 44 is separated from the sidewall 28 and the trench bottom 32 by a portion of the dielectric spacer 40. The upper portion of the field plate 44 is also separated from the adjacent section of the layer 20 by a portion of the dielectric spacer 40.

The field plate 46 includes an upper portion arranged above the top surface 13 of the semiconductor substrate 12 and a lower portion between the top surface 13 and the trench bottom 32. The lower portion of the field plate 46 is arranged adjacent to the sidewall 30 of the trench 26. The lower portion of the field plate 46 is separated from the sidewall 30 and the trench bottom 32 by a portion of the dielectric spacer 42. The upper portion of the field plate 46 is also separated from the adjacent section of the layer 20 by a portion of the dielectric spacer 42.

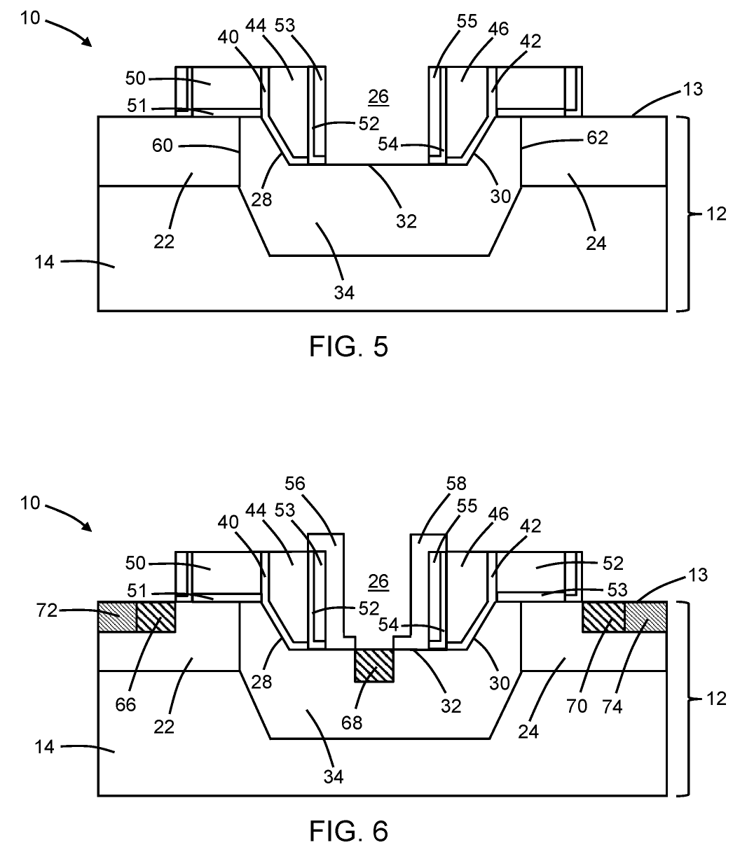

With reference to FIG. 5 in which like reference numerals refer to like features in FIG. 4 and at a subsequent fabrication stage, gates 48, 50 are formed by patterning the layer 20 with lithography and etching processes. The dielectric layer 18 is also patterned into sections that are respectively arranged as gate dielectric layers 49, 51 between the gates 48, 50 and the top surface 13 of the semiconductor substrate 12. The gate 48 overlies the top surface 13 of the semiconductor substrate 12, overlaps with an underlying portion of the well 24 that adjoins the drift well 34 along a p-n junction 62, and overlaps with an underlying portion of the drift well 34 between the sidewall 28 and the p-n junction 62. The gate 50 overlies the top surface 13 of the semiconductor substrate 12, overlaps with an underlying portion of the well 24 that adjoins the drift well 34 along a p-n junction 62, and overlaps with an underlying portion of the drift well 34 between the sidewall 30 and the p-n junction 62. The field plate 44 is positioned adjacent to the gate 48 with an upper portion of the dielectric spacer 40 laterally arranged between the field plate 44 and the gate 48. The field plate 46 is positioned adjacent to the gate 50 with an upper portion of the dielectric spacer 42 laterally arranged between the field plate 46 and the gate 50.

Dielectric spacers 52, 54 may be formed adjacent to the sidewalls of the field plate 44 and dielectric spacers 53, 55 may be formed adjacent to the sidewalls of the field plate 46. In an embodiment, the dielectric spacers 52, 54 may be comprised of silicon oxide (e.g., silicon dioxide) and the dielectric spacers 53, 55 may be comprised of silicon nitride. The dielectric spacer 52 may be L-shaped and the dielectric spacer 53 may be arranged on the horizontally-extending portion of the dielectric spacer 52. The dielectric spacer 54 may be L-shaped and the dielectric spacer 55 may be arranged on the horizontally-extending portion of the dielectric spacer 54.

With reference to FIG. 6 in which like reference numerals refer to like features in FIG. 5 and at a subsequent fabrication stage, a spacer 56 may be formed adjacent to the dielectric spacers 53 and a spacer 58 may be formed adjacent to the dielectric spacers 55. The spacers 56, 58 may be comprised of a different material than the dielectric spacers 53, 55. In an embodiment, the spacers 56, 58 may be comprised of silicon nitride if the dielectric spacers 53, 55 are comprised of silicon oxide. A lower portion of the spacer 56 may overlap with a portion of the semiconductor substrate 12 at the trench bottom 32, a central portion of the spacer 56 may be separated from the field plate 44 by the dielectric spacers 52, 53, and an upper portion of the spacer 56 may overlap with the dielectric spacers 52, 53. A lower portion of the spacer 58 may overlap with a portion of the semiconductor substrate 12 at the trench bottom 32, a central portion of the spacer 58 may be separated from the field plate 46 by the dielectric spacers 54, 55, and an upper portion of the spacer 56 may overlap with the dielectric spacers 54, 55.

Doped regions 66, 68, 70 and doped regions 72, 74 are formed in respective portions of the semiconductor substrate 12. More specifically, the doped region 66 and the doped region 72 are formed in portions of the well 22, the doped region 70 and the doped region 74 are formed in portions of the well 24, and the doped region 68 is formed in a portion of the drift well 34 and inside the trench 26 along the trench bottom 32. The doped regions 72, 74 may have an opposite conductivity type from the doped regions 66, 68, 70. The doped region 66 may abut and adjoin the doped region 72, and the doped region 70 may abut and adjoin the doped region 74. The doped regions 72, 74 may provide low-resistance connections to the wells 22, 24.

The doped region 66 and the doped region 70 may have an opposite conductivity type from the wells 22, 24. The doped region 68 may be doped to the same conductivity type as the drift well 34 but at a higher dopant concentration. The doped region 72 and the doped region 74 may have that same conductivity type as the wells 22, 24 but at a higher dopant concentration.

In an embodiment, the doped regions 66, 68, 70 may contain a concentration of an n-type dopant, such as phosphorus, to provide n-type conductivity. The doped regions 66, 68, 70 may be concurrently formed by selectively implanting ions, such as ions including the n-type dopant, with an implantation mask having openings defining the intended locations for the doped regions 66, 68, 70 in the semiconductor substrate 12. The implantation conditions, such as ion species, dose, and kinetic energy, may be selected to tune the electrical and physical characteristics of the doped regions 66, 68, 70. The spacers 56, 58 may self-align the formation of the doped region 68 in the semiconductor substrate 12.

In an embodiment, the doped regions 72, 74 may contain a concentration of a p-type dopant, such as boron, to provide p-type conductivity. The doped regions 72, 74 may be formed by selectively implanting ions, such as ions including the p-type dopant, with an implantation mask having openings defining the intended locations for the doped regions 72, 74 in the semiconductor substrate 12. The implantation conditions, such as ion species, dose, and kinetic energy, may be selected to tune the electrical and physical characteristics of the doped regions 72, 74.

The doped region 66 and the doped region 70 may represent sources of the laterally-diffused metal-oxide-semiconductor device and the doped region 68 may represent a drain of the laterally-diffused metal-oxide-semiconductor device. The field plate 44 is positioned adjacent to the doped region 68, the field plate 46 is also positioned adjacent to the doped region 68, and the doped region 68 is laterally positioned between the field plate 44 and the field plate 46. The dielectric spacers 52, 53 and spacer 56 may separate the doped region 68 from the field plate 44. The dielectric spacers 54, 55 and spacer 58 may separate the doped region 68 from the field plate 46. The doped region 68 representing the drain of the laterally-diffused metal-oxide-semiconductor device is located inside the trench 26 and adjoins a portion of the trench bottom 32 and, for that reason, is considered to be recessed relative the top surface 13 of the semiconductor substrate 12.

The doped region 66, representing a source of the laterally-diffused metal-oxide-semiconductor device, is laterally positioned in a spaced-relationship with the sidewall 28 of the trench 26. The doped region 70, representing another source of the laterally-diffused metal-oxide-semiconductor device, is laterally positioned in a spaced-relationship with the sidewall 30 of the trench 26. The doped region 68, representing a drain of the laterally-diffused metal-oxide-semiconductor device, is laterally positioned between the sidewall 28 of the trench 26 and the sidewall 30 of the trench 26. The gate 48 is laterally positioned between the doped region 66 and the sidewall 28 of the trench 26. The gate 50 is laterally positioned between the doped region 70 and the sidewall 30 of the trench 26.

The field plates 44, 46 may be slabs that extend parallel to the length of the gates 48, 50. Both field plates 44, 46 are laterally positioned between the gate 48 and the gate 50. The field plate 44 is laterally positioned between the gate 48 and the doped region 68. The field plate 46 is laterally positioned between the gate 50 and the doped region 68. The doped region 68 is laterally positioned between the field plate 44 and the field plate 46.

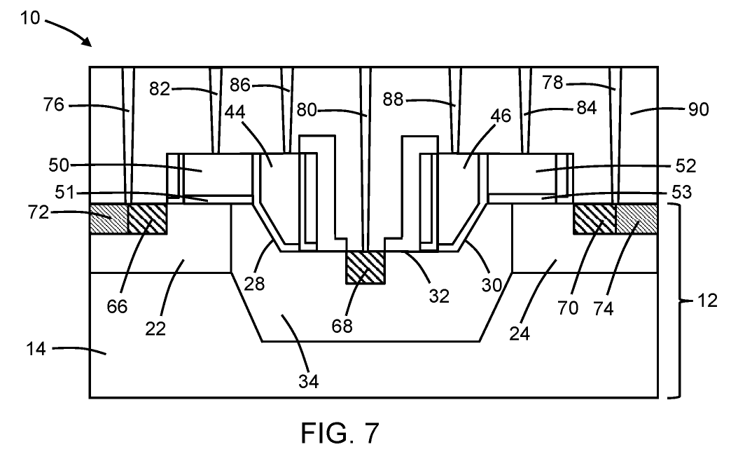

With reference to FIG. 7 in which like reference numerals refer to like features in FIG. 6 and at a subsequent fabrication stage, silicide layers (not shown) may be formed on the adjacent doped regions 66, 72, the adjacent doped regions 70, 74, the doped region 68, and the field plates 44, 46. One or more contacts 76 may be formed are physically and electrically coupled to the doped region 66 and the doped region 72. One or more contacts 78 may be formed that are physically and electrically coupled to the doped region 70 and the doped region 74. One or more contacts 80 may be formed that physically and electrically coupled to the doped region 68. One or more contacts 82 may be formed that are physically and electrically coupled to the gate 48. One or more contacts 84 may be formed that are physically and electrically coupled to the gate 50. One or more contacts 86 may be formed that are physically and electrically coupled to the field plate 44. One or more contacts 88 may be formed that are physically and electrically coupled to the field plate 46. The contacts 76, 78, 80, 82, 84, 86, 88 may be arranged in a dielectric layer 90.

The structure 10 may exhibit improved performance in comparison with a conventional laterally-diffused metal-oxide-semiconductor device. For example, the field plates 44, 46 may cause a more uniform distribution of the electric field in the drift well 34 during operation of the laterally-diffused metal-oxide-semiconductor device. As another example, the drift well 34 is interrupted by the introduction of the trench 26 between the sources and the drain, which requires charge carriers to flow about the trench 26 and the field plates 44, 46 when traveling between the sources and the drain. As a result, the drain-source on-resistance and the size of the laterally-diffused metal-oxide-semiconductor device may be reduced.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. A feature may “overlie” another feature if the feature is positioned in elevation over another feature. Different features may “overlap” if a feature extends over, and covers all or a part of, another feature. A feature may “underlie” another feature if the feature is positioned in elevation below another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a laterally-diffused metal-oxide-semiconductor device, the structure comprising:
a semiconductor substrate including a trench, the trench having a first sidewall;
a first source in the semiconductor substrate;
a drain in the semiconductor substrate, the drain positioned inside the trench;
a first gate laterally positioned between the drain and the first source; and
a first field plate adjacent to the first sidewall of the trench, the first field plate laterally positioned between the first gate and the drain.

2. The structure of claim 1 wherein the first field plate comprises polycrystalline silicon.

3. The structure of claim 1 wherein the semiconductor substrate includes a top surface, the trench has a trench bottom, and the first sidewall extends fully from the top surface to the trench bottom.

4. The structure of claim 3 wherein the first sidewall is inclined at an acute angle relative to a horizontal plane of the trench bottom.

5. The structure of claim 3 wherein the first field plate includes a first portion arranged above the top surface and a second portion between the top surface and the trench bottom.

6. The structure of claim 5 wherein the second portion of the first field plate is laterally positioned between the first sidewall and the drain.

7. The structure of claim 1 wherein the trench has a second sidewall opposite from the first sidewall, and the drain is laterally positioned between the first sidewall and the second sidewall.

8. The structure of claim 7 wherein the semiconductor substrate includes a top surface, the trench has a trench bottom, the first sidewall extends between the top surface and the trench bottom, and the first gate is laterally positioned between the first sidewall of the trench and the first source.

9. The structure of claim 8 wherein the first gate is positioned on the top surface of the semiconductor substrate adjacent to the trench.

10. The structure of claim 8 further comprising:
a drift well in the semiconductor substrate, the drift well including a first portion,
wherein the trench extends into the drift well, and the first gate is positioned on the top surface of the semiconductor substrate overlapping with the first portion of the drift well.

11. The structure of claim 10 wherein the drift well includes a second portion, and the trench bottom overlaps with the second portion of the drift well.

12. The structure of claim 11 further comprising:
a body well in the semiconductor substrate,
wherein the first source is positioned in the body well, the body well adjoins the first portion of the drift well along a p-n junction, and the first portion of the drift well is laterally positioned between the first sidewall and the first field plate.

13. The structure of claim 1 the trench includes a second sidewall, and further comprising:
a second field plate adjacent to the second sidewall of the trench.

14. The structure of claim 13 wherein the drain is laterally positioned between the first field plate and the second field plate.

15. The structure of claim 14 further comprising:
a second source in the semiconductor substrate; and
a second gate laterally positioned between the second field plate and the second source,
wherein the second field plate is laterally positioned between the second gate and the drain.

16. The structure of claim 13 wherein the semiconductor substrate includes a top surface, the first field plate includes a first portion arranged above the top surface and a second portion between the top surface and the trench bottom, and the second field plate includes a first portion arranged above the top surface and a second portion between the top surface and the trench bottom.

17. The structure of claim 13 further comprising:
a first contact coupled to the first field plate; and
a second contact coupled to the second field plate.

18. The structure of claim 1 further comprising:
a contact coupled to the first field plate.

19. The structure of claim 1 further comprising:
a first dielectric spacer;
a second dielectric spacer laterally between the first dielectric spacer and the drain; and
a third dielectric spacer laterally between the first dielectric spacer and the first field plate.

20. A method of forming a structure for a laterally-diffused metal-oxide-semiconductor device, the method comprising:
forming a trench in a semiconductor substrate, wherein the trench has a sidewall;
forming a source in the semiconductor substrate;
forming a drain in the semiconductor substrate, wherein the drain is positioned inside the trench;
forming a gate laterally positioned between the drain and the source; and
forming a field plate adjacent to the sidewall of the trench, wherein the field plate is laterally positioned between the gate and the drain.
